(19) United States
(12) Patent Application Publication
(10) Pub. No.: US 2020/0296840 A1
(43) Pub. Date: Sep. 17, 2020

(54) Folded Multilayered Flexible Circuit Board and Methods of Manufacturing Thereof

(71) Applicant: OSI Electronics, Inc., Hawthorne, CA (US)

(72) Inventors: Konstantine Karavakis, Pleasanton, CA (US); Robert Jung, Fremont, CA (US)

(21) Appl. No.: 16/352,742

(22) Filed: Mar. 13, 2019

(51) Int. Cl. H05K 3/46; H05K 1/02; H05K 1/11; H05K 3/00; H05K 3/40; H05K 3/22

(52) U.S. Cl. CPC H05K 3/46; H05K 1/028; H05K 1/115; H05K 2201/09036; H05K 3/4038; H05K 3/22; H05K 3/0044

(57) ABSTRACT

A multilayered flexible circuit board (FCB) may be fabricated by folding a single panel made of a substrate having conducting regions separated by a folding region. After conducting layers with patterned circuit areas are positioned on a single panel, the panel is folded to thereby cause one portion of the panel to stack atop the other portion of the panel and create the multilayered FCB. The multilayered FCB may have three, four, five, six, seven or eight conducting layers stacked upon one another.

### FIELD

The present specification is related generally to the field of flexible circuit boards. More specifically, the present specification is related to manufacturing a multilayered flexible circuit board from a single flexible panel, substrate or laminate.

### BACKGROUND

Flexible circuit boards (FCBs) are electronic circuits that are frequently used in a variety of modern electronic devices. A FCB comprises circuit traces and electronic components deposited onto a flexible substrate or laminate. FCBs typically comprise plastic substrates and etched thin metal foils and are so named because of their ability to bend, twist or flex. They have the advantage of being thin, thus saving space, and of being easily moldable to the shape of the electronic device. They are often used to form a connection between two separate circuits.

With continued demand for miniaturization and high-density circuit designs, FCBs have become more complex in design and manufacturing process. Also, FCBs have been migrating from the use of two-layered FCBs to the use of multilayered FCBs. Manufacturing such multilayered FCBs tends to be expensive because they involve significant manual labor. Multiple layers are often fabricated on multiple boards or panels that have to be handled and aligned by hand which is a time-consuming process.

Thus, there is a need for a process of manufacturing multilayer FCBs from a single flexible panel or laminate. There is also a need for an efficient manufacturing process that enables high yield and low cycle time for fabricating stair-case multilayer FCBs.

### SUMMARY

The following embodiments and aspects thereof are described and illustrated in conjunction with systems, tools and methods, which are meant to be exemplary and illustrative, and not limiting in scope. The present application discloses numerous embodiments.

The present specification discloses a circuit board comprising a flexible substrate layer having a top surface, a bottom surface, a first side and a second side, wherein the first side is positioned opposite to the second side and wherein the flexible substrate layer has a thickness defined by a distance from the top surface to the bottom surface; a first plurality of conducting portions positioned on the top surface and first side of the flexible substrate layer; a second plurality of conducting portions positioned on the top surface and first side of the flexible substrate layer; a folding region located between the first plurality of conducting portions and the second plurality of conducting portions, wherein a width of the folding region is equal to or greater than 1.3 times the thickness of the flexible substrate and wherein the folding region only comprises the flexible substrate layer and does not comprise any of the first plurality or second plurality of conducting portions; and a groove formed in the folding region.

Optionally, a width of the groove is equal to at least a thickness of the substrate layer plus a minimum of 50% of the thickness of the substrate layer.

Optionally, the circuit board further comprises a third plurality of conducting portions positioned on the second side of the flexible substrate layer and a fourth plurality of conducting portions positioned on the second side of the flexible substrate layer. Optionally, the third plurality of conducting portions and fourth plurality of conducting portions are separated by the folding region.

Optionally, the flexible substrate layer comprises a dielectric material. Optionally, the circuit board further comprises a plurality of vias, wherein at least one of the plurality of vias is positioned to interconnect one of the third plurality of conducting portions to one of the first plurality of conducting portions. Optionally, the circuit board further comprises a plurality of vias, wherein at least one of the plurality of vias is positioned to interconnect one of the fourth plurality of conducting portions to one of the second plurality of conducting portions.

The present specification also discloses a method of manufacturing a multilayered circuit board using a flexible panel, said flexible panel having first and second sides, the method comprising: forming a first plurality of conducting portions on the first side of the flexible panel and a second plurality of conducting portions on the first side of the panel, wherein the first plurality of conducting portions and the second plurality of conducting portions are separated by a first folding region; forming a third plurality of conducting portions on the second side of the flexible panel and a fourth plurality of conducting portions on the second side of the flexible panel, wherein the third plurality of conducting portions and the fourth plurality of conducting portions are separated by a second folding region; cutting a portion of the first folding region and the second folding region; and applying a force to fold the fourth plurality of conducting portions over the third plurality of conducting portions to thereby cause the second folding region to bend from a substantially linear shape to a substantially curved shape; and applying a force to fold the second plurality of conducting portions over the first plurality of conducting portions to thereby cause the first folding region to bend from a substantially linear shape to a substantially curved shape.

Optionally, each of the first folding region and the second folding region comprises a groove formed by said cutting. Optionally, a width of the groove is a function of a thickness of the flexible panel.

Optionally, the method further comprises forming a plurality of vias, wherein at least one of the plurality of vias is formed to interconnect one of the third plurality of conducting portions to one of the first plurality of conducting portions. Optionally, the method further comprises forming a plurality of vias, wherein at least one of the plurality of vias is positioned to interconnect one of the fourth plurality of conducting portions to one of the second plurality of conducting portions. Optionally, the plurality of vias are filled with a metal.

Optionally, the flexible panel comprises a substrate layer of dielectric material.

Optionally, the method further comprises applying a dielectric adhesive film to cover a portion of the flexible panel prior to applying the force. Optionally, the method further comprises, after applying the force, laminating a surface of the first plurality of conducting portion and not of the second plurality of conducting portions, third plurality of conducting portions, or fourth plurality of conducting portions.

Optionally, a width of each of the first folding region and the second folding region is in a range of a value equal to a thickness of the flexible panel to a value equal to 200% of the thickness of the flexible panel.

Optionally, a thickness of the flexible panel ranges from 25 μm to 200 μm.

Optionally, a thickness of each of the first, second, third, and fourth plurality of conducting layers ranges from 12 μm to 75 μm.

Optionally, the method further comprises cutting a curved surface of the first folding region or a curved surface of the second folding region.

The aforementioned and other embodiments of the present shall be described in greater depth in the drawings and detailed description provided below.

### BRIEF DESCRIPTION OF THE DRAWINGS

These and other features and advantages of the present specification will be further appreciated, as they become better understood by reference to the following detailed description when considered in connection with the accompanying drawings:

FIG. 1A illustrates a cross-sectional view of a panel comprising a plurality of layers, circuit areas and vias, in accordance with some embodiments of the present specification;

FIG. 1B illustrates a cross-sectional view of the panel of FIG. 1A with a groove, in accordance with some embodiments of the present specification; FIG. 1C illustrates a cross-sectional view of the panel of FIG. 1B with an adhesive film on a portion of a conducting layer, in accordance with some embodiments of the present specification;

FIG. 1D illustrates a cross-sectional view of the panel of FIG. 1C showing vias filled with a conductive material, in accordance with some embodiments of the present specification;

FIG. 1E illustrates a cross-sectional view of the panel of FIG. 1D with a folding torque being applied to the panel, in accordance with some embodiments of the present specification;

FIG. 1F illustrates a cross-sectional view of a four-layered flexible circuit board, in accordance with some embodiments of the present specification;

FIG. 2A illustrates a cross-sectional view of a panel comprising a plurality of layers, circuit areas and vias, in accordance with some embodiments of the present specification;

FIG. 2B illustrates a cross-sectional view of the panel of FIG. 2A with first, second and third grooves, in accordance with some embodiments of the present specification;

FIG. 2C illustrates a cross-sectional view of the panel of FIG. 2B with adhesive films on portion of three conducting layers, in accordance with some embodiments of the present specification;

FIG. 2D illustrates a cross-sectional view of the panel of FIG. 2C showing vias filled with a conductive material, in accordance with some embodiments of the present specification;

FIG. 2E illustrates a cross-sectional view of the panel of FIG. 2D with first, second and third folding torques being applied to the panel, in accordance with some embodiments of the present specification; and,

FIG. 2F illustrates a cross-sectional view of an eight-layered flexible circuit board, in accordance with some embodiments of the present specification.

### DETAILED DESCRIPTION

The present specification discloses a multilayered flexible circuit board (FCB) fabricated by folding a single panel comprising a substrate sandwiched between a flexible dielectric substrate. In accordance with some aspects of the present specification, conducting layers comprising a plurality of patterned circuit areas are positioned on a single panel. The panel is folded for stacking the layers on top of one another to form the multilayered FCB. In various embodiments, the multilayered FCB may comprise three, four, five, six, seven, eight or more conducting layers stacked upon one another. As the layer count increases, the overall initial board length increases.

A “via” (vertical interconnect access) is an electrical connection between layers in a flexible electronic circuit that passes through the plane of one or more layers.

The present specification is directed towards multiple embodiments. The following disclosure is provided in order to enable a person having ordinary skill in the art to practice the invention. Language used in this specification should not be interpreted as a general disavowal of any one specific embodiment or used to limit the claims beyond the meaning of the terms used therein. The general principles defined herein may be applied to other embodiments and applications without departing from the spirit and scope of the invention. Also, the terminology and phraseology used is for the purpose of describing exemplary embodiments and should not be considered limiting. Thus, the present invention is to be accorded the widest scope encompassing numerous alternatives, modifications and equivalents consistent with the principles and features disclosed. For purpose of clarity, details relating to technical material that is known in the technical fields related to the invention have not been described in detail so as not to unnecessarily obscure the present invention.

In the description and claims of the application, each of the words “comprise” “include” and “have”, and forms thereof, are not necessarily limited to members in a list with which the words may be associated. It should be noted herein that any feature or component described in association with a specific embodiment may be used and implemented with any other embodiment unless clearly indicated otherwise.

As used herein, the indefinite articles “a” and “an” mean “at least one” or “one or more” unless the context clearly dictates otherwise.

### Overview of a Four-Layered Flexible Circuit Board

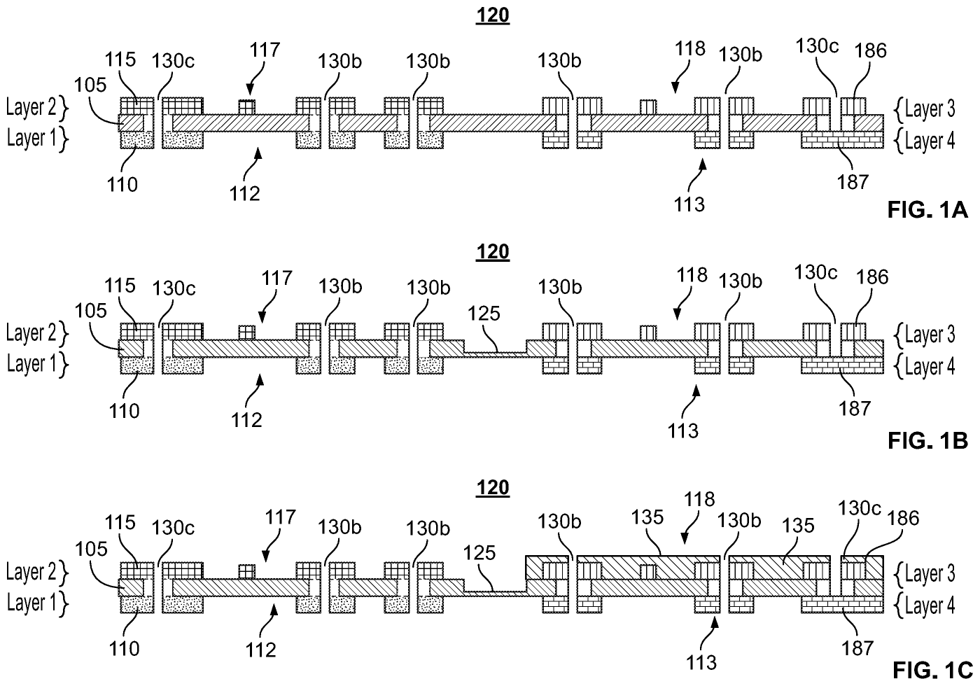

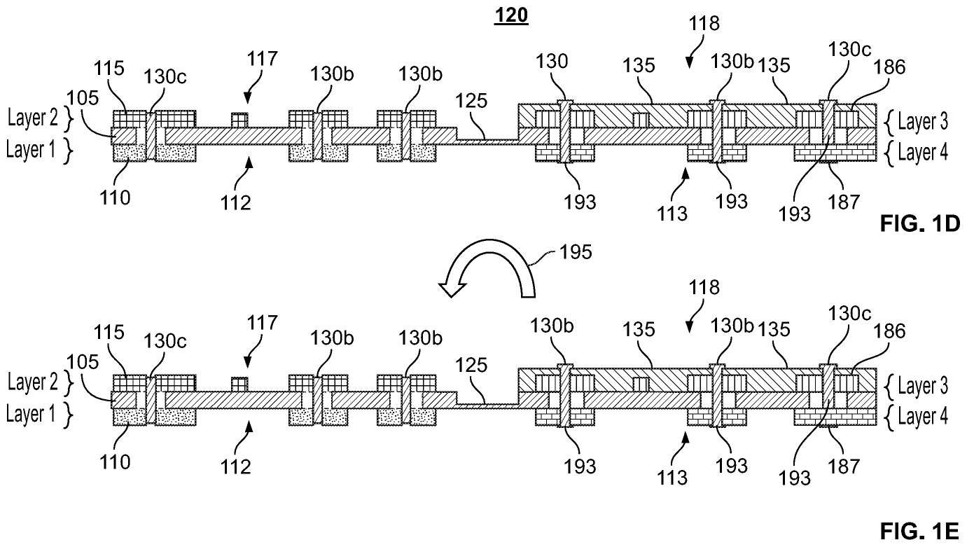

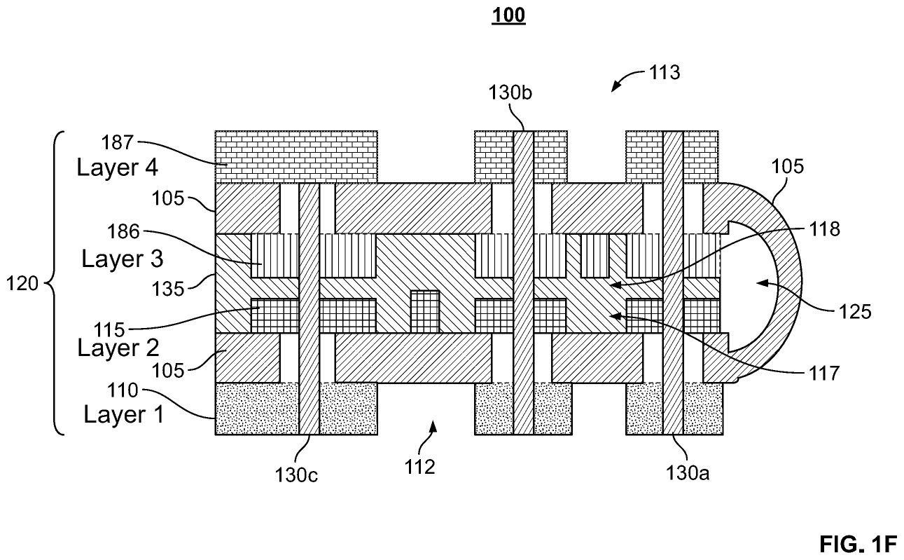

FIG. 1F illustrates a cross-sectional view of a four-layered flexible circuit board (FCB) 100 in folded configuration, in accordance with embodiments of the present specification. In embodiments, the four-layered FCB 100 is fabricated from a single panel 120. In some embodiments, the single panel 120 is a flexible conductor-clad laminate comprising a dielectric insulating substrate 105, first and fourth conducting layers 110, 187 positioned on a first side of the substrate 105 and second and third conducting layers 115, 186 positioned on a second, opposing side of the substrate 105. First and fourth circuit areas 112, 113 are formed respectively on the first and fourth conducting layers 110, 187 while second and third circuit areas 117, 118 are formed respectively on the second and third conducting layers 115, 186.

An area or region 125 is positioned between the first and second circuit areas 112, 113 and the third and fourth circuit areas 117, 118. The area 125 is subject to predefined constraints to ensure that the single panel 120 can be effectively folded. First, the area 125 must have a sufficient width to provide a sufficient extent of material to bend and thereby allow circuit areas 118, 113 to be folded over circuit areas 117, 112, respectively. The width is a function of the thickness of the panel 120. For example, if panel 120 is 0.004″ thick, the width of the area 125 should be at least the thickness of the panel plus a minimum of 50% of the panel thickness, or at least 0.006″ wide. Accordingly, the width between the second and third circuit areas 117, 118 is equal to or greater than 1.3 times, preferably 1.5 times, the overall thickness of the panel 120 itself.

Second, the area 125 must comprise a groove, indentation, void, or other decrease in material (collectively referred to as a “groove”) that enables and facilitates the bending of the panel 120 upon itself. It should be appreciated that the groove 125 forms a region of decreased material, and therefore increased flexibility, between the second and third conducting layers 115, 186 thereby facilitating folding of the third and fourth circuit areas 118, 113 over the second and first circuit areas 117, 112 of the panel 120 or vice versa. In another embodiment, the groove 125 may be formed between the first and fourth conducting layers 110, 187 to facilitate folding and stacking of the fourth and third circuit areas 113, 118 over the first and second circuit areas 112, 117 of the panel 120 or vice versa. In some embodiments, first and second grooves are formed respectively between the second and third conducting layers 115, 186 and the first and fourth conducting layers 110, to enable folding on any one of the two sides of the panel 120.

In some embodiments, the groove 125 is formed between the second and third conducting layers 115, 186 and positioned such that the groove 125 lies substantially between the second and third conducting layers 115, 186 and also substantially between the first and fourth conducting layers 110, 187. In accordance with an aspect of the present specification, the groove 125 enables folding of the third and fourth circuit areas 118, 113 over the second and first circuit areas 117, 112 of the panel 120. Thus, in folded configuration, the second circuit area 117 is position over, or stacked over, the first circuit area 112, the third circuit area 118 is stacked over the second circuit area 117 and the fourth circuit area 113 is stacked over the third circuit area 118 to form the four-layered FCB 100 from the single panel 120. In various embodiments, the cross-sectional shape of the groove 125 may be square, rectangular, V-shaped, U-shaped, semi-circular, patterned, perforated or corrugated.

In various embodiments, the circuit areas 112, 113, 117 and 118 comprise a plurality of surface-mounted electronic components that are electrically connected to each other through a plurality of conductive pads or lands, conductive traces, and conductive vias disposed on the surface and on or through various layers of the FCB 100. A conductive via is a formed hole lined or filled with a conductor metal 193. In various embodiments, conductive vias may interconnect any two conducting layers, or reach entirely through every layer of the FCB 100. For example, conductive vias 130a and 130b, having annular metallic formations, such as copper, facilitate interconnection of all four circuit areas 112, 117, 118, 113 while via 130c interconnects first, second and third circuit areas 112, 117, 118 of the FCB 100. In accordance with some embodiments, the FCB 100 comprises through-hole vias, such as vias 130a, 130b and blind via, such as via 130c. However, in various embodiments, presence of through-hole, blind and/or buried vias, depends upon the design and interconnection needs of a multilayered FCB.

In some embodiments, a dielectric adhesive film (such as, for example, Bondply) 135 is applied to cover a portion of a side of the panel 120 comprising the third circuit area 118 formed on the third conducting layer 186. The film 135 enables adherence of the third conducting layer 186 to the second conducting layer 115 upon folding of the panel 120.

### Manufacturing Steps of the Four-Layered FCB

FIGS. 1A through 1E illustrate cross-sectional views of exemplary manufacturing steps of the four-layered FCB 100, in accordance with embodiments of the present specification. While the manufacturing steps are henceforth being described with reference to the four-layered FCB 100, it should be appreciated that by repeating the steps FCBs of multiple layers such as 5, 6, 7 or 8 layers may be fabricated.

In accordance with some aspects, the manufacturing process of the present specification facilitates efficient production or fabrication of multilayered FCBs with different layers in terms of length and/or width. For example, a layer or board size for circuit areas 112 and 117 fabricated on one panel may be different from the layer or board size for circuit areas 113 and 118 fabricated on another panel. Thus, the manufacturing process of the present specification makes it easier to fabricate stair-case multilayer FCBs since, in the manufacturing process of the present specification, the layers are aligned and folded upon, as described herein, even if their lengths are different. Conventional fabrication methods pose a significant challenge in terms of singulation of stair-case constructions when the panels are stacked and laminated all at once. In accordance with an aspect, the final singulation is avoided in the fabrication method of the present invention.

In accordance with some aspects, the manufacturing process of the present specification enables high yield and lower cycle time for stair-case multilayer FCBs as compared to prior art manufacturing processes. Persons of ordinary skill in the art would appreciate that in a stair-case multilayer FCB all layers do not tend to be of the same length and/or width. As discussed earlier, in conventional processes, it is difficult, if not impossible, to manufacture stair-case multilayers since all the panels that the individual boards are on are laminated together. Since some of the inner layers may be smaller in size than others this makes it very difficult to route or singulate such designs. In accordance with some aspects, a plurality of circuit areas (such as areas 112, 113, 117, 118) are processed on one panel 120, instead of separate panels, as conventionally done through circuitization and interconnection between the conducting layers of the panel 120 using vias.

Referring now to FIG. 1A, in some embodiments, the starting material of the FCB (such as the FCB 100 of FIG. 1F) is a flexible substrate layer 105 having first and second opposing sides. A first conducting film comprising first and fourth conducting layers 110, 187 is laminated on the first side, and a second conducting film comprising second and third conducting layers 115, 186 is laminated to the second side of the substrate layer 105 thereby resulting in the flexible panel 120. Lamination of the substrate layer 105 is completed by applying pressure at an elevated temperature on the sandwich comprising the first conducting film, intermediate substrate layer 105, and the second conducting film.

In embodiments, the flexible panel 120 is a substantially rectangular strip of a predetermined length to support fabrication, thereon, of a plurality of FCBs. In some embodiments, adhesive layers are positioned under the first and second conducting films, respectively, to help the films adhere or bond to the sides of the substrate layer 105. The adhesive layers may be applied as a sheet, a spray, a gel, or a paste. In some embodiments, the adhesive layers may be impregnated into the substrate layer 105.

In embodiments, the substrate layer 105 comprises a flexible electrically insulating (dielectric) material such as, but not limited to, polyimide (PI), polyether ether ketone (PEEK), polyester (PET), polyethylene naphthalate (PEN), polyetherimide (PEI), along with various fluoropolymers (FEP) and polyimide copolymer films, or other flexible insulating materials including polyester or silk. In various embodiments, a thickness of the substrate layer 105 ranges from 25 μm to 200 μm.

In embodiments, the adhesive layers comprise bonding adhesives such as, but not limited to, an epoxy, an insulating potting compound, acrylic adhesives, or polyimide adhesives. In some embodiments, the first and second conducting films comprise metal foils such as, for example, copper foil, aluminum foil, copper-beryllium alloy, or a metal filled conductive polymer. In various embodiments, a thickness of the first and second conducting films ranges from 12 μm to 75 μm.

In some embodiments, flexible panels are also fabricated without an adhesive layer. In such embodiments, sputtering methods are used for vacuum depositing a layer of Ni (Nickel) or Ni alloy coating in a range of 0.05 to 0.02 μm followed by copper deposition of 0.1-0.2 μm. Additional copper thickness, in a range of 12 to 75 μm, is also added by standard electroplating methods.

Next, the layout for the first, second, third and fourth circuit areas 112, 117, 118 and 113 is designed using PCB design software such as CAD, Gerber, or Genesis software, for example. The layout design comprises the relative positioning of the circuit areas 112, 113, 117 and 118 with respect to each other on the first, second, third and fourth conducting layers 110, 115, 186, 187 of the panel 120. The layout design also comprises the sizes of the circuit areas 112, 113, 117 and 118. The layout design further stipulates a width of the groove or channel 125 to facilitate folding of the panel 120.

Thereafter, a plurality of openings, holes or vias, such as the vias 130b, 130c, are formed within the first, second, third and fourth circuit areas 112, 117, 118 and 113 by an ultraviolet (UV) based laser, a carbon dioxide based laser, or by any other known methods, such as, but not limited to, mechanical drilling, depth-controlled laser drilling or punching. In an embodiment, for exemplary illustrative purposes, the vias 130b, 130c are shown as through-hole and blind via. However, in alternate embodiments a plurality of through-hole, blind and/or buried vias may be formed depending upon the desired design and surface mount of the FCB. In various embodiments, one or more openings or holes, formed in the FCB, comprise at least one of the following types: a) tooling holes formed outside of the circuit areas (such as, the circuit areas 112, 113, 117 and 118) for positioning the panel 120 during subsequent processing. The sequence of FCB fabrication steps requires close alignment from one process to the next, and the tooling holes are used with locating pins at each step to achieve accurate registration/alignment; b) insertion holes for inserting electronic component leads therein; and c) via holes, such as the vias 130b, 130c, that are later electroplated and used as conducting paths between various conducting layers of the FCB.

In some embodiments, once the vias 130b, 130c are formed they are cleaned or de-smeared using plasma cleaning to remove unwanted residue or by-products left behind by laser or mechanical drilling.

Persons of ordinary skill in the art would appreciate that direct electroplating of the vias 130b, 130c is not possible since the first and second conducting layers 110, 115 and the third and fourth conducting layers 186, 187 are separated by the dielectric substrate layer 105. In order to allow electroplating, a conductive region or bridge must be coated over the substrate layer 105 within the vias 130b, 130c. In embodiments, the conductive bridge is created by shadow plating or electroless copper plating.

In some embodiments, the vias 130b, 130c are subjected to electroless copper plating where the panel 120 is immersed in a series of baths that include a catalyst (usually palladium) followed by an alkaline, chelated solution of copper. Copper is thereby chemically bonded to all surfaces that are immersed. This chemically bonded coating is rather thin, but it allows electrical current to flow across the dielectric, which enables electroplating. As a result of electroless plating, the vias 130b, 130c have a coating of copper that is both electrically and mechanically robust.

In alternate embodiments, the vias 130b, 130c are subjected to shadow plating wherein the panel 120 is immersed in a solution with conductive carbon particles. The carbon adheres to the entire surface, creating a very thin, fragile layer. A micro-etch is then performed that removes the carbon from the conducting layers, within the vias 130b, 130c, so that only the dielectric areas (within the vias 130b, 130c) remain coated. It should be appreciated that the vias 130b, 130c may or may not be filled with copper. In some embodiments, if the vias 130b, 130c are small enough in a range of 25-75 μm in diameter then they may be filled with copper during a copper electroplating process such as by dot plating.

Next, first, second, third and fourth circuit areas 112, 117, 118 and 113 designated on the on the first, second, third and fourth conducting layers 110, 115, 186, 187 of the panel 120 are circuitized or patterned through a process of photolithography. In photolithography, the first, second, third and fourth conducting layers 110, 115, 186, 187 to be patterned are first coated with a light sensitive photoresist. To transfer an image to the resist, an optical mask or photomask is used to control which portions of the dry resist sheet are exposed to light and which are not. The photomask is created using commercially available CAD software resulting in a Gerber file defining the mask pattern needed for photomask generation.

The photoresist is then exposed to light through the patterned photomask thereby transferring the mask pattern. The photoresist is sensitive to exposure to short wavelength light such as ultraviolet light. After exposing the photoresist, the resist is developed causing the photoresist to be washed away in some regions and retained in others as defined by the portions of the photoresist exposed to light and those is the shadow of the photomask. After developing the photoresist, organic photoresist layer mimics the pattern of the photomask through which it was exposed, covering the areas 112, 113, 117, 118 in some regions and not in others.

The portions that are protected by the photoresist and those that are exposed to etching depend on whether a positive or a negative photoresist is employed. Because the photoresist comprises an organic compound, it is relatively insensitive to exposure to acids, especially after hard baking. The metal is then etched in acid and thereafter the mask is also removed. In embodiments, the photolithographic process is repeated for each of the first, second, third and fourth conducting layers 110, 115, 186, 187 to generate patterned circuit areas 112, 117, 118 and 113.

Next, as shown in FIG. 1B, the groove or channel 125 is formed between the second and third conducting layers 115, 186 so that the groove 125 lies substantially between the second and third patterned circuit areas 117, 118 and also substantially between the first and fourth patterned circuit areas 112, 113 of the panel 120. In various embodiments, a cross-sectional shape of the groove 125 may be rectangular, square, V-shaped, U-shaped, semi-circular, patterned, perforated or corrugated.

Now, as shown in FIG. 1C, the dielectric adhesive film (such as, for example, Bondply) 135 is applied to cover at least a portion of the third conducting layer 186. The film 135 is pre-lasered to be used for bonding. Openings, in the film 135, are made by using laser, for example, in positions where the vias 130b, 130c are located.

Thereafter, as shown in FIG. 1D, the vias 130b, 130c are filled with a metal or other electrically conductive material 193 such as copper or silver paste. In some embodiments, to fill the vias 130b, 130c, metal is grown through electroplating to overflow the filled vias 130b, 130c and on to the surfaces of the corresponding conducting layers. The overflowed metal is then etched back to smoothen the surfaces of the corresponding conducting layers. In some embodiments, the vias 130b, 130c are filled with a solder paste or other conductive material is deposited or printed to fill the vias 130b, 130c. It should be appreciated, that while in some embodiments the step of filling the vias 130b, 130c with conductive material is being performed prior to folding the panel but in other embodiments this step may be accomplished towards the end of the manufacturing process, specifically after folding.

Finally, as shown in FIG. 1E, a torque (depicted by means of an arrow 195) is applied to fold the third and fourth patterned circuit areas 118, 113 over the second and first patterned circuit areas 115, 110. In some embodiments, alignment of each layer, during the folding process, is accomplished by using fiducials (for example, 2 to 4 in numbers) which may be located along a periphery of each layer. In some embodiments, a method of pin alignment is utilized for aligning each layer to the next with the dielectric in between them. Once all layers are aligned, in the multi-layered FCB form, then they get bonded in place using vacuum lamination with heat and pressure.

It should be appreciated that the groove 125 provides a region of weakness and a mechanism for folding the third and fourth conducting layers 186, 187 respectively comprising the third and fourth patterned circuit areas 118, 113 over the second and first conducting layers 115, 110 respectively comprising the second and first patterned circuit areas 117, 112. The third conducting layer 186 gets tacked in place over the second conducting layer 115 with the dielectric adhesive film 135 that has openings where the vias 130b, 130c are.

After folding, the folded FCB 100 (FIG. 1F) along with the dielectric adhesive film 135, which will bond all the layers together except in positions or areas where openings of the vias 130B, 130C exist, is laminated to cure the dielectric adhesive film 135. A signature of the final product will be a dielectric material that extends from the base of the first layer 110 to the top surface of fourth layer 113, thereby electrically separating the layers.

Depending on the FCB design a plurality of connections are done by means of the vias 130b, 130c-either through all the circuit areas 112, 113, 117, 118 or selectively between specific layers. The vias 130b, 130c are pre-plated with a conductive medium thereby enabling the electrical connection. The conductive medium can be silver, copper, gold or any of their alloys with resistivity close to copper. The method of application of the conductive medium in the vias 130b, 130c can be and not limited to dispensing, stenciling, screen printing, among other processes. Finally, the FCB 100 is tested and inspected for electrical connections and external appearance.

Referring back to FIG. 1B, in some embodiments, the width ‘w’ of the groove or channel 125 is a function of the thickness of the panel 120. For example, if panel 120 is 0.004″ thick, the width of the groove 125 should be at least the thickness of the panel plus a minimum of 50% of the panel thickness, or at least 0.006″ wide. In various embodiments, the width ‘w’ and depth ‘d’ of the groove 125 depends upon at least one, some or all of the respective thicknesses of the first, second, third and fourth conducting layers 110, 115, 186, 187, the substrate layer 105 and the dielectric adhesive film 135. In some embodiments, the width ‘w’ of the groove 125 ranges from a value equal to 50% of the substrate layer 105 to a value equal to 300% of the substrate layer 105, including all whole number or fractional numerical increments therein. In some embodiments, the width ‘w’ of the groove 125 ranges from a value equal to 50% of the total thickness of all layers (110, 115, 186, 187, 105, 135) to a value equal to 300% of the total thickness of all layers (110, 115, 186, 187, 105, 135), including all whole number or fractional numerical increments therein. In some embodiments, the depth ‘d’ of the groove 125 is a function of the respective thicknesses of one, more, or all of the layers in the panel 120.

### Overview of an Eight-Layered Flexible Circuit Board

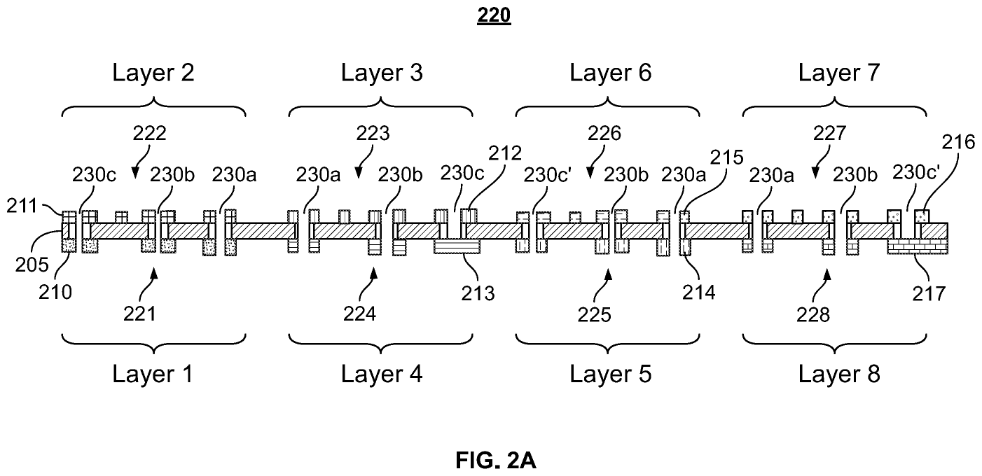

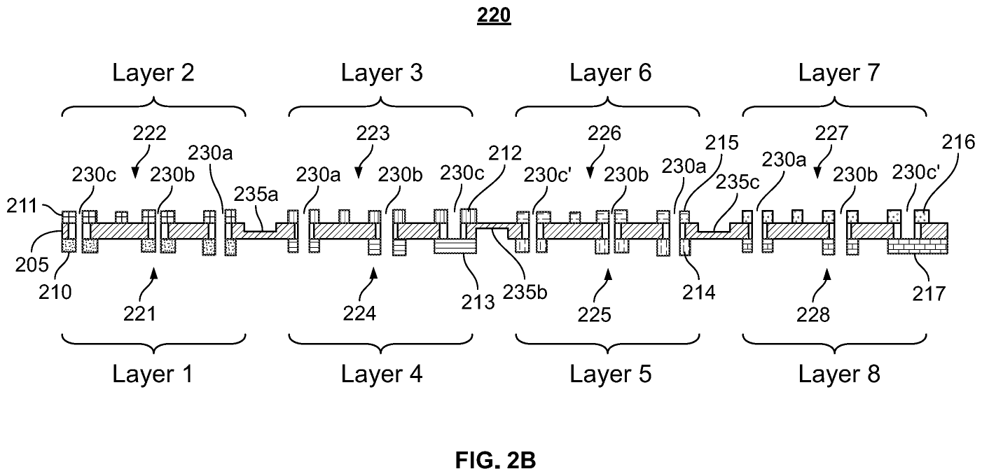

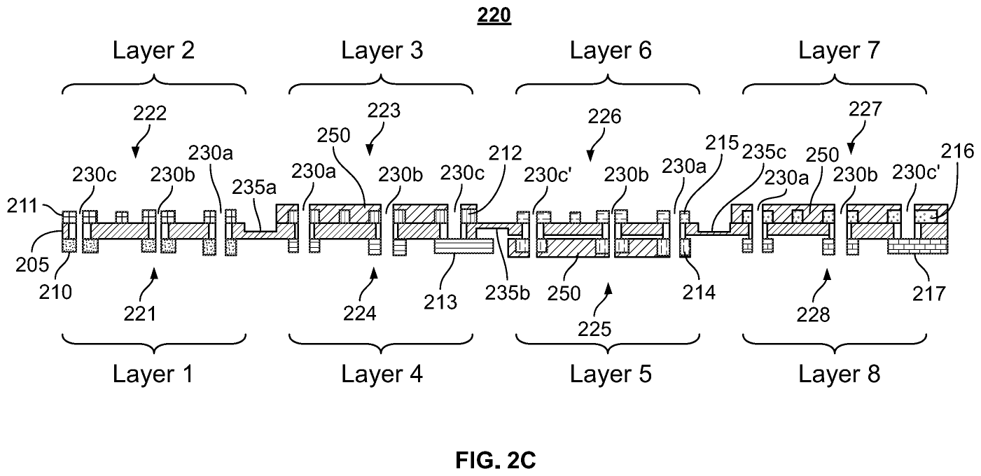

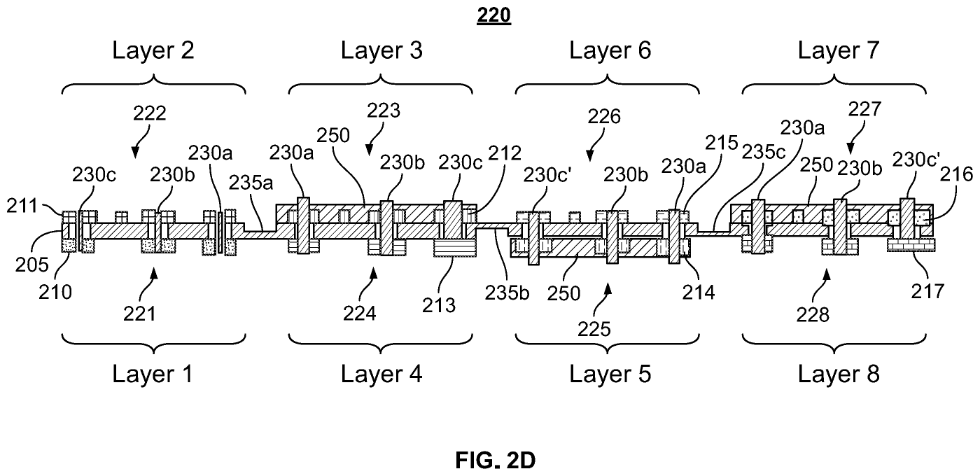

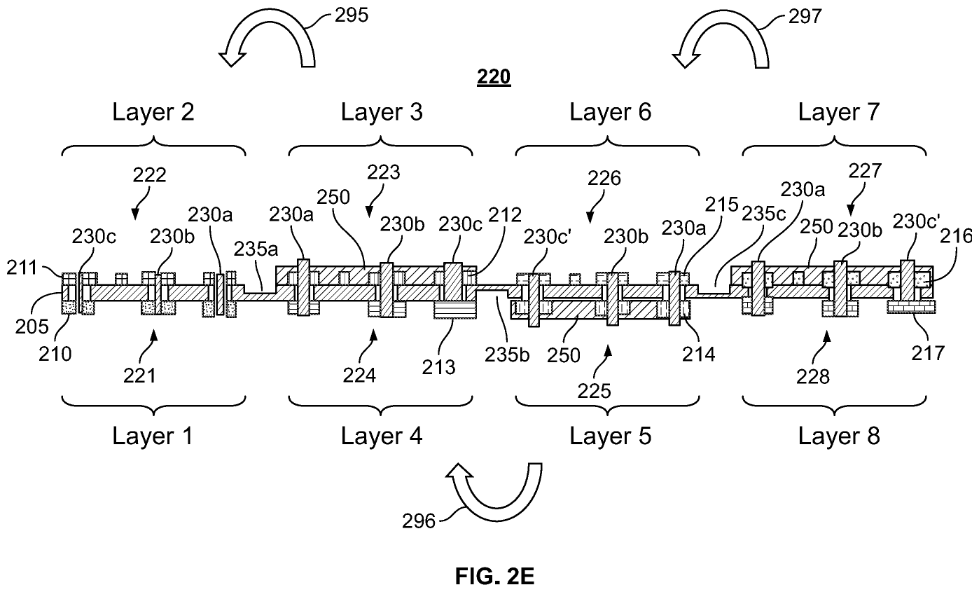

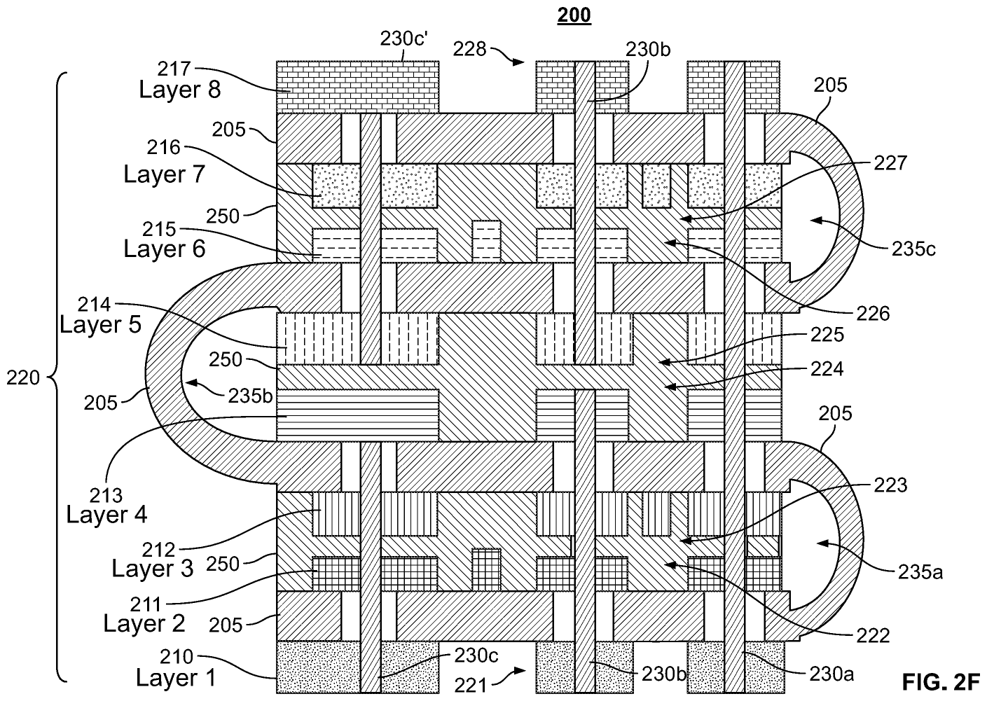

FIG. 2F illustrates a cross-sectional view of an eight-layered flexible circuit board (FCB) 200 in folded configuration, in accordance with embodiments of the present specification. In embodiments, the eight-layered FCB 100 is fabricated from a single panel 220. In some embodiments, the single panel 220 is a flexible conductor-clad laminate comprising a dielectric insulating substrate 205 with first, fourth, fifth and eight conducting layers 210, 213, 214 and 217 positioned on a first side of the substrate 205 and second, third, sixth and seventh conducting layers 211, 212, 215 and 216 positioned on a second, opposing side of the substrate 205. First, fourth, fifth and eighth circuit areas 221, 224, 225 and 228 are formed respectively on the first, fourth, fifth and eight conducting layers 210, 213, 214 and 217 while second, third, sixth and seventh circuit areas 222, 223, 226 and 227 are formed respectively on the second, third, sixth and seventh conducting layers 211, 212, 215 and 216.

In some embodiments, a first area or region 235a is positioned between the second and third circuit areas 222, 223, a second area or region 235b is positioned between the sixth and seventh circuit areas 226, 227 while a third area or region 235c is positioned between the fourth and fifth circuit areas 224, 225. The first, second and third areas 235a, 235b, 235c are subject to predefined constraints to ensure that the single panel 220 can be effectively folded. First, the areas 235a, 235b, 235c must have a sufficient width to provide a sufficient extent of material to bend and thereby allow circuit areas 223, 224 to be folded over circuit areas 221, 222 and allow circuit areas 225, 226 to be folded over circuit areas 227, 228. The width is a function of the thickness of the panel 220. For example, if panel 220 is 0.004″ thick, the width of the areas 235a, 235b, 235c should be at least the thickness of the panel plus a minimum of 50% of the panel thickness, or at least 0.006″ wide. Accordingly, a first width between the second and third circuit areas 222, 223, a second width between the fourth and fifth circuit areas 224, 225 and a third width between the sixth and seventh circuit areas 226, 227 is each equal to or greater than 1.3 times, preferably 1.5 times, the overall thickness of the panel 220 itself.

Second, each of the areas 235a, 235b, 235c must comprise a groove, indentation, void, or other decrease in material (collectively referred to as a “groove”) that enables and facilitates the bending of the panel 220 upon itself. It should be appreciated that each of the grooves 235a, 235b, 235c forms a region of weakness thereby facilitating folding and stacking of the first, second, third, fourth, fifth, sixth and seventh circuit areas 212, 222, 223, 224, 225, 226, 227 and 228 over one another.

In some embodiments, a) the first groove 235a is formed between the second and third conducting layers 211, 212 and positioned such that the groove 225a lies substantially between the second and third conducting layers 211, 212 and also substantially between the first and fourth conducting layers 210, 213, b) the second groove 235b is formed between the fourth and fifth conducting layers 213, 214 and positioned such that the groove 225b lies substantially between the fourth and fifth conducting layers 213, 214 and also substantially between the third and sixth conducting layers 212, 215, and c) the third groove 235c is formed between the sixth and seventh conducting layers 215, 216 and positioned such that the groove 225c lies substantially between the sixth and seventh conducting layers 215, 216 and also substantially between the fifth and eight conducting layers 214, 217.

In accordance with an aspect of the present specification, the grooves 235a, 235b, 235c respectively enable folding of the third and fourth circuit areas 223, 224 over the second and first circuit areas 222, 221, folding of the fifth and sixth circuit areas 225, 226 over the fourth and third circuit areas 224, 223 and folding of the seventh and eighth circuit areas 227, 228 over the sixth and fifth circuit areas 226, 225 of the panel 220. Thus, in folded configuration, the second circuit area 222 is position over, or stacked over, the first circuit area 221, the third circuit area 223 is stacked over the second circuit area 222, the fifth circuit area 225 is stacked over the fourth circuit area 224 and the seventh circuit area 227 is stacked over the sixth circuit area 226 to form the eight-layered FCB 200 from the single panel 220. In various embodiments, the cross-sectional shape of each of the grooves 235a, 235b, 235c may be square, rectangular, V-shaped, U-shaped, semi-circular, patterned, perforated or corrugated.

In various embodiments, the circuit areas 212, 222, 223, 224, 225, 226, 227 and 228 comprise a plurality of surface-mounted electronic components that are electrically connected to each other through a plurality of conductive pads or lands, conductive traces, and conductive vias disposed on the surface and on or through various layers of the FCB 200. In various embodiments, conductive vias may interconnect at least two conducting layers, or reach entirely through every layer of the FCB 200. For example, conductive via 230a facilitates interconnection of all eight circuit areas 212, 222, 223, 224, 225, 226, 227 and 228, while via 230c interconnects first, second, third and fourth circuit areas 212, 222, 223 and 224 and via 230c′ interconnects fifth, sixth, and seventh circuit areas 225, 226 and 227 of the FCB 200. In accordance with some embodiments, the FCB 200 comprises through-hole via, such as via 230a, blind vias, such as vias 230b, 230c and buried via, such as via 230c′. Thus, in various embodiments, presence of through-hole, blind and/or buried vias, depends upon the design and interconnection needs of a multilayered FCB.

In some embodiments, a dielectric adhesive film (such as, for example, Bondply) 250 is applied to cover the third and seventh circuit areas 223, 227 (formed on the third and seventh conducting layers 212, 216) as well as to cover the fifth circuit area 225 (formed on the fifth conducting layer 214). The film 250 enables adherence of a) the third conducting layer 212 to the second conducting layer 211, b) the fifth conducting layer 214 to the fourth conducting layer 213 and c) the seventh conducting layer 227 to the sixth conducting layer 226 upon folding of the panel 220.

### Manufacturing Steps of the Eight-Layered FCB

FIGS. 2A through 2E illustrate cross-sectional views of exemplary manufacturing steps of the four-layered FCB 200, in accordance with embodiments of the present specification.

In accordance with some aspects, the manufacturing process of the present specification enables high yield and lower cycle time for stair-case multilayer FCBs as compared to prior art manufacturing processes. Persons of ordinary skill in the art would appreciate that in a stair-case multilayer FCB all layers do not tend to be of the same length and/or width. As discussed earlier, in conventional processes, it is difficult, if not impossible, to manufacture stair-case multilayers since all the panels that the individual boards are on are laminated together. Since some of the inner layers may be smaller in size than others this makes it very difficult to route or singulate such designs. In accordance with some aspects, a plurality of circuit areas (such as areas 212, 222, 223, 224, 225, 226, 227 and 228) are processed on one panel 220, instead of separate panels, as conventionally done through circuitization and interconnection between the conducting layers of the panel 220 using vias.

Referring now to FIG. 2A, in some embodiments, the starting material of the FCB 200 is a flexible substrate layer 205 having first and second opposing sides. A first conducting film comprising first, fourth, fifth and eighth conducting layers 210, 213, 214 and 217 is laminated on the first side, and a second conducting film comprising second, third, sixth and seventh conducting layers 222, 223, 226 and 227 is laminated to the second side of the substrate layer 205 thereby resulting in the flexible panel 220. Lamination of the substrate layer 205 is completed by applying pressure at an elevated temperature on the sandwich comprising the first conducting film, intermediate substrate layer 205, and the second conducting film.

In embodiments, the flexible panel 220 is a substantially rectangular strip of a predetermined length to support fabrication, thereon, of a plurality of FCBs. In some embodiments, adhesive layers are positioned under the first and second conducting films, respectively, to help the films adhere or bond to the sides of the substrate layer 205. The adhesive layers may be applied as a sheet, a spray, a gel, or a paste. In some embodiments, the adhesive layers may be impregnated into the substrate layer 205.

In embodiments, the substrate layer 205 comprises a flexible electrically insulating (dielectric) material such as, but not limited to, polyimide (PI), polyether ether ketone (PEEK), polyester (PET), polyethylene naphthalate (PEN), polyetherimide (PEI), along with various fluoropolymers (FEP) and polyimide copolymer films, or other flexible insulating materials including polyester or silk. In various embodiments, a thickness of the substrate layer 205 ranges from 25 μm to 200 μm.

In embodiments, the adhesive layers comprise bonding adhesives such as, but not limited to, an epoxy, an insulating potting compound, acrylic adhesives, or polyimide adhesives. In some embodiments, the first and second conducting films comprise metal foils such as, for example, copper foil, aluminum foil, copper-beryllium alloy, or a metal filled conductive polymer. In various embodiments, a thickness of the first and second conducting films ranges from 12 μm to 75 μm.

In some embodiments, flexible panels are also fabricated without an adhesive layer. In such embodiments, sputtering methods are used for vacuum depositing a layer of Ni (Nickel) or Ni alloy coating in a range of 0.05 to 0.02 μm followed by copper deposition of 0.1-0.2 μm. Additional copper thickness, in a range of 12 to 75 μm, is also added by standard electroplating methods.

Next, layout for the first, second, third, fourth, fifth, sixth and seventh circuit areas 212, 222, 223, 224, 225, 226, 227 and 228 is designed using PCB design software such as CAD, Gerber, or Genesis software, for example. The layout design comprises the relative positioning of the circuit areas 212, 222, 223, 224, 225, 226, 227 and 228 with respect to each other on the first, second, third, fourth, fifth, sixth and seventh conducting layers 210, 211, 212, 213, 214, 215, 216 and 217 of the panel 220. The layout design also comprises the sizes of the circuit areas 212, 222, 223, 224, 225, 226, 227 and 228. The layout design further stipulates a width of each of the first, second and third grooves 235a, 235b and 235c to facilitate folding of the panel 220.

Thereafter, a plurality of openings, holes or vias, such as the vias 230a, 230b and 230c, are formed within the first, second, third, fourth, fifth, sixth and seventh circuit areas 212, 222, 223, 224, 225, 226, 227 and 228 by an ultraviolet (UV) based laser, a carbon dioxide based laser, or by any other known methods, such as, but not limited to, mechanical drilling, depth-controlled laser drilling or punching. In an embodiment, for exemplary illustrative purposes, the via 230a, os shown as a through-hole, the via 230b, 230c is shown as blind vias while the via 230c′ is shown as a buried via. Thus, in various embodiments a plurality of through-hole, blind and/or buried vias may be formed depending upon the desired design and surface mount of the FCB. In various embodiments, one or more openings or holes, formed in the FCB, comprise at least one of the following types: a) tooling holes formed outside of the circuit areas (such as, the circuit areas 212, 222, 223, 224, 225, 226, 227 and 228) for positioning the panel 220 during subsequent processing. The sequence of FCB fabrication steps requires close alignment from one process to the next, and the tooling holes are used with locating pins at each step to achieve accurate registration/alignment; b) insertion holes for inserting electronic component leads therein; and c) via holes, such as the vias 230a, 230b, 230c and 230c′, that are later electroplated and used as conducting paths between various conducting layers of the FCB.

In some embodiments, once the vias 230a, 230b, 230c and 230c′ are formed they are cleaned or de-smeared using plasma cleaning to remove unwanted residue or by-products left behind by laser or mechanical drilling.

Persons of ordinary skill in the art would appreciate that direct electroplating of the vias 230a, 230b, 230c and 230c′ is not possible since the first and second conducting layers 210, 211, the third and fourth conducting layers 212, 213, the fifth and sixth conducting layers 214, 215 and the seventh and eight conducting layers 216, 217 are separated by the dielectric substrate layer 205. In order to allow electroplating, a conductive region or bridge must be coated over the substrate layer 205 within the vias 230a, 230b, 230c and 230c′. In embodiments, the conductive bridge is created by shadow plating or electroless copper plating.

In some embodiments, the vias 230a, 230b, 230c and 230c′ are subjected to electroless copper plating where the panel 220 is immersed in a series of baths that include a catalyst (usually palladium) followed by an alkaline, chelated solution of copper. Copper is thereby chemically bonded to all surfaces that are immersed. This chemically bonded coating is rather thin, but it allows electrical current to flow across the dielectric, which enables electroplating. As a result of electroless plating, the vias 230a, 230b, 230c and 230c′ have a coating of copper that is both electrically and mechanically robust.

In alternate embodiments, the vias 230a, 230b, 230c and 230c′ are subjected to shadow plating wherein the panel 220 is immersed in a solution with conductive carbon particles. The carbon adheres to the entire surface, creating a very thin, fragile layer. A micro-etch is then performed that removes the carbon from the conducting layers, within the vias 230a, 230b, 230c and 230c′, so that only the dielectric areas (within the vias 230a, 230b, 230c and 230c′) remain coated. It should be appreciated that the vias 230a, 230b, 230c and 230c′ may or may not be filled with copper. In some embodiments, if the vias 230a, 230b, 230c and 230c′ are small enough in a range of 25-75 μm in diameter then they may be filled with copper during a copper electroplating process such as by dot plating.

Next, the first, second, third, fourth, fifth, sixth and seventh circuit areas 212, 222, 223, 224, 225, 226, 227 and 228 designated on the on the first, second, third, fourth, fifth, sixth and seventh conducting layers 210, 211, 212, 213, 214, 215, 216 and 217 of the panel 220 are circuitized or patterned through photolithography wherein the first, second, third, fourth, fifth, sixth and seventh conducting layers 210, 211, 212, 213, 214, 215, 216 and 217 to be patterned are first coated with a light sensitive photoresist. To transfer an image to the resist, an optical mask or photomask is used to control which portions of the dry resist sheet are exposed to light and which are not. The photomask is created using commercially available CAD software resulting in a Gerber file defining the mask pattern needed for photomask generation.

The photoresist is then exposed to light through the patterned photomask thereby transferring the mask pattern. The photoresist is sensitive to exposure to short wavelength light such as ultraviolet light. After exposing the photoresist, the resist is developed causing the photoresist to be washed away in some regions and retained in others as defined by the portions of the photoresist exposed to light and those is the shadow of the photomask. After developing the photoresist, organic photoresist layer mimics the pattern of the photomask through which it was exposed, covering the areas 212, 222, 223, 224, 225, 226, 227 and 228 in some regions and not in others.

The portions that are protected by the photoresist and those that are exposed to etching depend on whether a positive or a negative photoresist is employed. Because the photoresist comprises an organic compound, it is relatively insensitive to exposure to acids, especially after hard baking. The metal is then etched in acid and thereafter the mask is also removed. In embodiments, the photolithographic process is repeated for each of the first, second, third, fourth, fifth, sixth and seventh conducting layers 210, 211, 212, 213, 214, 215, 216 and 217 to generate patterned circuit areas 212, 222, 223, 224, 225, 226, 227 and 228.

Next, as shown in FIG. 2B, the first groove 235a is formed between the second and third conducting layers 211, 212 and positioned such that the groove 225a lies substantially between the second and third conducting layers 211, 212 and also substantially between the first and fourth conducting layers 210, 213, the second groove 235b is formed between the fourth and fifth conducting layers 213, 214 and positioned such that the groove 225b lies substantially between the fourth and fifth conducting layers 213, 214 and also substantially between the third and sixth conducting layers 212, 215, and the third groove 235c is formed between the sixth and seventh conducting layers 215, 216 and positioned such that the groove 225c lies substantially between the sixth and seventh conducting layers 215, 216 and also substantially between the fifth and eight conducting layers 214, 217.

In various embodiments, a cross-sectional shape of the grooves 235a, 235b and 235c may be rectangular, square, V-shaped, U-shaped, semi-circular, patterned, perforated or corrugated.

Now, as shown in FIG. 2C, the dielectric adhesive film (such as, for example, Bondply) 250 is applied to cover at least a portion of the third and seventh circuit areas 223, 227 (formed on the third and seventh conducting layers 212, 216) as well as to cover the fifth circuit area 225 (formed on the fifth conducting layer 214). The film 250 is pre-lasered to be used for bonding. Openings, in the film 250, are made by using laser, for example, in positions where the vias 230a, 230b, 230c and 230c′ are located.

Thereafter, as shown in FIG. 2D, the vias 230a, 230b, 230c and 230c′ are filled with a metal or other electrically conductive material such as copper or silver paste. In some embodiments, to fill the vias 230a, 230b, 230c and 230c′, metal is grown through electroplating to overflow the filled vias 230a, 230b, 230c and 230c′ and on to the surfaces of the corresponding conducting layers. The overflowed metal is then etched back to smoothen the surfaces of the corresponding conducting layers. In some embodiments, the vias 230a, 230b, 230c and 230c′ are filled with a solder paste or other conductive material is deposited or printed to fill the vias 230a, 230b, 230c and 230c′. It should be appreciated, that while in some embodiments the step of filling the vias 230a, 230b, 230c and 230c′ with conductive material is being performed prior to folding the panel but in other embodiments this step may be accomplished towards the end of the manufacturing process, specifically after folding.

Finally, as shown in FIG. 2E, a first torque (depicted by means of an arrow 295) is applied to fold the third and fourth circuit areas 223, 224 over the second and first circuit areas 222, 221, a second torque (depicted by means of an arrow 296) is then applied to fold the fifth and sixth circuit areas 225, 226 over the fourth and third circuit areas 224, 223 and finally a third torque (depicted by means of an arrow 297) is applied to fold the seventh and eighth circuit areas 227, 228 over the sixth and fifth circuit areas 226, 225 of the panel 220.

In some embodiments, alignment of each layer, during the folding process, is accomplished by using fiducials (for example, 2 to 4 in numbers) which may be located along a periphery of each layer. In some embodiments, a method of pin alignment is utilized for aligning each layer to the next with the dielectric in between them. Once all layers are aligned, in the multi-layered FCB form, then they get bonded in place using vacuum lamination with heat and pressure.

It should be appreciated that the grooves 235a, 235b and 235c provide regions of weakness and a mechanism for folding: a) the third and fourth conducting layers 211, 212 respectively comprising the third and fourth patterned circuit areas 223, 224 over the second and first conducting layers 211, 210 respectively comprising the second and first patterned circuit areas 222, 221, b) the fifth and sixth conducting layers 214, 215 respectively comprising the fifth and sixth patterned circuit areas 225, 226 over the fourth and third conducting layers 213, 212 respectively comprising the fourth and third patterned circuit areas 224, 223, and c) the seventh and eight conducting layers 216, 217 respectively comprising the seventh and eighth patterned circuit areas 227, 228 over the sixth the fifth conducting layers 215, 214 respectively comprising the sixth and fifth patterned circuit areas 226, 225.

The third conducting layer 212 gets tacked in place over the second conducting layer 211, the fifth conducting layer 214 gets tacked in place over the fourth conducting layer 213 while the seventh conducting layer 216 gets tacked in place over the sixth conducting layer 215 with the dielectric adhesive films 250 that have openings where the vias 230a, 230b, 230c and 230c′ are.

After folding, the folded FCB 200 (FIG. 1F) along with the dielectric adhesive film 250, which will bond all the layers together except in positions or areas where openings of the vias 230a, 230b, 230c and 230c′ exist, is laminated to cure the dielectric adhesive films 250. A signature of the final product will be a dielectric material that extends from the base of the first layer 210 to the top surface of eighth layer 217, thereby electrically separating the layers 210, 211, 212, 213, 214, 215, 216 and 217.

Depending on the FCB design a plurality of connections are done by means of the vias 230a, 230b, 230c and 230c′-either through all the circuit areas 212, 222, 223, 224, 225, 226, 227 and 228 and/or selectively between specific layers. The vias 230a, 230b, 230c and 230c′ are pre-plated with a conductive medium thereby enabling the electrical connection. The conductive medium can be silver, copper, gold or any of their alloys with resistivity close to copper. The method of application of the conductive medium in the vias 230a, 230b, 230c and 230c′ can be and not limited to dispensing, stenciling, screen printing, among other processes. Finally, the FCB 200 is tested and inspected for electrical connections and external appearance.

Referring back to FIG. 2B, in some embodiments, the width ‘w’ of each of the grooves or channels 235a, 235b and 235c is a function of the thickness of the panel 220. For example, if panel 220 is 0.004″ thick, the width of each of the grooves 235a, 235b and 235c should be at least the thickness of the panel plus a minimum of 50% of the panel thickness, or at least 0.006″ wide. In various embodiments, the width ‘w’ and depth ‘d’ of each of the grooves 235a, 235b and 235c depends upon at least one, some or all of the respective thicknesses of the first, second, third, fourth, fifth, sixth and seventh conducting layers 210, 211, 212, 213, 214, 215, 216 and 217, the substrate layer 205 and the dielectric adhesive film 250. In some embodiments, the width ‘w’ of each of the grooves 235a, 235b and 235c ranges from a value equal to 50% of the thickness of the substrate layer 205 to a value equal to 300% of the substrate layer 205, and any percentage increment therein. In some embodiments, the width ‘w’ of each of the grooves 235a, 235b and 235c ranges from a value equal to 50% of the total thickness of all layers (205, 210, 211, 212, 213, 214, 215, 216, 217 and 250) to a value equal to 300% of the total thickness of all layers, and any percentage increment therein. In some embodiments, the depth ‘d’ of each of the grooves 235a, 235b and 235c is a function of the respective thicknesses of one, more, or all of the layers in the panel 220.

The above examples are merely illustrative of the many applications of the system and method of present specification. Although only a few embodiments of the present specification have been described herein, it should be understood that the present specification might be embodied in many other specific forms without departing from the spirit or scope of the specification. Therefore, the present examples and embodiments are to be considered as illustrative and not restrictive, and the specification may be modified within the scope of the appended claims.

1. A multi-layered circuit board having at least four layers comprising
a contiguous flexible substrate that forms the at least four layers, wherein the contiguous flexible substrate is folded such that a first portion of the contiguous flexible substrate is positioned atop a second potion of the contiguous flexible substrate and a folding region is adjacent to, and separates, the first portion and the second portion, wherein a bottom of the first portion of the contiguous flexible substrate forms a first of the at least four layers, a top of the first portion of the contiguous flexible substrate forms a second of the at least four layers, a bottom of the second portion of the contiguous flexible substrate forms a third of the at least four layers, and a top of the second portion of the contiguous flexible substrate forms a fourth of the at least four layers;
a first plurality of conducting portions positioned on the first of the at least four layers;
a second plurality of conducting portions positioned on the fourth of the at least four layers; and
at least one via positioned to directly interconnect one of the first plurality of conducting portions to one of the second plurality of conducting portions, wherein the folding region has a width that is equal to or greater than 1.3 times a thickness of the contiguous flexible substrate and wherein the folding region comprises a groove.

2. The multi-layered circuit board of claim 1, wherein a width of the groove is equal to at least the thickness of the contiguous flexible substrate plus a minimum of 50% of the thickness of the contiguous flexible substrate.

3. The multi-layered circuit board of claim 1, further comprising a third plurality of conducting portions positioned on the second of the at least four layers and a fourth plurality of conducting portions positioned on the third of the at least four layers.

4. The multi-layered circuit board of claim 3, wherein the third plurality of conducting portions and fourth plurality of conducting portions are separated by the folding region.

5. The multi-layered circuit board of claim 1, wherein the contiguous flexible substrate layer comprises a dielectric material.

6. The multi-layered circuit board of claim 4, further comprising at least one via positioned to directly interconnect one of the third plurality of conducting portions to one of the first plurality of conducting portions.

7. The multi-layered circuit board of claim 4, further comprising at least one via positioned to interconnect one of the fourth plurality of conducting portions to one of the second plurality of conducting portions.

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. The multi-layered circuit board of claim 1 wherein the folding region only comprises the contiguous flexible substrate and does not comprise any electronic components.

22. The multi-layered circuit board of claim 1 wherein the contiguous flexible substrate comprises a conductor-clad laminate and a dielectric insulating substrate.

23. The multi-layered circuit board of claim 1 further comprising at least one via placing one of the at least four layers in electrical communication with another of the at least four layers.

24. The multi-layered circuit board of claim 1 further comprising dielectric adhesive film positioned between two or more of the at least four layers.

25. The multi-layered circuit board of claim 1, wherein a thickness of the contiguous flexible substrate ranges from 25 μm to 200 μm.

26. A multi-layered circuit board having at least four layers comprising:
a contiguous flexible substrate that forms the at least four layers, wherein the contiguous flexible substrate is folded such that a first portion of the contiguous flexible substrate is positioned atop a second potion of the contiguous flexible substrate and a folding region separates the first portion and the second portion, wherein a bottom of the first portion of the contiguous flexible substrate forms a first of the at least four layers, a top of the first portion of the contiguous flexible substrate forms a second of the at least four layers, a bottom of the second portion of the contiguous flexible substrate forms a third of the at least four layers, and a top of the second portion of the contiguous flexible substrate forms a fourth of the at least four layers;
a plurality of electronic components positioned on each of the at least four layers, wherein the folding region has a width that is equal to or greater than 1.3 times a thickness of the contiguous flexible substrate; and
at least one via positioned to directly interconnect one of the plurality of electronic components on one of the four layers to one of the plurality of electronic components on another one of the at least four layers.

27. The multi-layered circuit board of claim 26, further comprising a groove positioned in the folding region, wherein the groove has a thickness that is less than the thickness of the contiguous flexible substrate.

28. The multi-layered circuit board of claim 27, wherein a width of the groove is equal to at least a thickness of the contiguous flexible substrate plus a minimum of 50% of the thickness of the flexible substrate.

29. The multi-layered circuit board of claim 26, wherein the fourth of the at least four layers and first of the at least four layers are separated by the folding region.

30. The multi-layered circuit board of claim 26, wherein the contiguous flexible substrate comprises a dielectric material.

31. (canceled)

32. The multi-layered circuit board of claim 26, wherein the folding region only comprises the contiguous flexible substrate and does not comprise any electronic components.

33. The multi-layered circuit board of claim 26, further comprising dielectric adhesive film positioned between two or more of the at least four layers.
